(19) United States
(12) Patent Application Publication
(10) Pub. No.: US 2021/0257301 A1
(43) Pub. Date: Aug. 19, 2021

(54) SEMICONDUCTOR DEVICE AND METHOD FOR FABRICATING SEMICONDUCTOR DEVICE

(71) Applicant: Kioxia Corporation, Minato-ku (JP)

(72) Inventor: Hiroshi MATSUMOTO, Yokkaichi (JP)

(73) Assignee: Kioxia Corporation, Minato-ku (JP)

(21) Appl. No.: 16/932,895

(22) Filed: Jul. 20, 2020

(30) Foreign Application Priority Data
Feb. 18, 2020 (JP) 2020-025339

(51) Int. Cl. H01L 23/535; H01L 27/11524; H01L 27/11556; H01L 27/1157; H01L 27/11582; H01L 23/522; H01L 23/528; H01L 21/768

(52) U.S. Cl. CPC H01L 23/535; H01L 27/11524; H01L 27/11556; H01L 27/1157; H01L 27/11582; H01L 23/5226; H01L 21/76877; H01L 21/76805; H01L 21/76816; H01L 21/76831; H01L 21/76843; H01L 21/76895; H01L 23/5283

(57) ABSTRACT

A semiconductor device according to an embodiment includes a plurality of conductive layers, a plurality of contacts, a plurality of dielectric members, a channel body, and a memory film. The plurality of conductive layers is stacked to be separated from each other and formed in a plate shape extending in a direction intersecting a stacking direction so as to extend over first and second regions. Each of the plurality of contacts penetrates a different number of conductive layers among the plurality of conductive layers and is connected to a different conductive layer of the plurality of conductive layers at a different one of positions of the plurality of conductive layers stacked in the first region. Each of the plurality of dielectric members is arranged from substantially same height position to a different one of height positions and connected to a different one of the plurality of contacts.

### CROSS-REFERENCE TO RELATED APPLICATION

This application is based upon and claims the benefit of priority from Japanese Patent Application No. 2020-025339 filed on Feb. 18, 2020 in Japan, the entire contents of which are incorporated herein by reference.

### FIELD

Embodiments described herein relate generally to a semiconductor device and a method for fabricating the semiconductor device.

### BACKGROUND

In the development of semiconductor devices, particularly semiconductor storage devices, miniaturization of memory cells has been advanced in order to achieve large capacity, low cost, and the like. For example, development of a three-dimensional NAND flash memory device in which memory cells are three-dimensionally arranged has been advanced. In such a three-dimensional NAND flash memory device, a NAND string in which memory cells are connected in a direction (so-called vertical direction) perpendicular to a word line layer surface is formed in a word line layer stacked with a dielectric layer interposed therebetween. As a result, higher integration is achieved as compared with a case where memory cells are two-dimensionally arranged. In such a three-dimensional NAND flash memory device, conductive layers are formed in a staircase shape so as to be shifted for each layer as a structure for connecting a wire of another layer to a conductive layer serving as a word line of each layer stacked, and thus, a structure of easily connecting with contacts from the upper layer side is formed. However, since the formation of holes for arranging contacts for the layers having different depths is performed by batch processing, in some cases, the holes may penetrate the target conductive layer and reach the conductive layer of the lower layer side, and thus, electrical connection with the conductive layer of the lower layer side may be made.

### BRIEF DESCRIPTION OF THE DRAWINGS

FIG. 1 is across-sectional view illustrating an example of a configuration of a semiconductor device according to Embodiment 1;

FIG. 2 is a cross-sectional view illustrating an example of a connection portion between a contact and a conductive layer in Embodiment 1;

FIG. 3 is a flowchart illustrating the main processes of a method for fabricating the semiconductor device according to Embodiment 1;

FIG. 4 is a cross-sectional view illustrating a portion of the processes of the method for fabricating the semiconductor device according to Embodiment 1;

FIG. 5 is a cross-sectional view illustrating a portion of the processes of the method for fabricating the semiconductor device according to Embodiment 1;

FIG. 6 is a cross-sectional view illustrating a portion of the processes of the method for fabricating the semiconductor device according to Embodiment 1;

FIG. 7 is a cross-sectional view illustrating an example of a configuration of a memory cell region in Embodiment 1;

FIG. 8 is a cross-sectional view illustrating a portion of the processes of the method for fabricating the semiconductor device according to Embodiment 1;

FIG. 9 is a cross-sectional view illustrating a portion of the processes of the method for fabricating the semiconductor device according to Embodiment 1;

FIG. 10 is a cross-sectional view illustrating a portion of the processes of the method for fabricating the semiconductor device according to Embodiment 1;

FIG. 11 is a cross-sectional view illustrating a portion of the processes of the method for fabricating the semiconductor device according to Embodiment 1;

FIG. 12 is a cross-sectional view illustrating a portion of the processes of the method for fabricating the semiconductor device according to Embodiment 1;

FIG. 13 is a cross-sectional view illustrating a portion of the processes of the method for fabricating the semiconductor device according to Embodiment 1;

FIG. 14 is a cross-sectional view illustrating a portion of the processes of the method for fabricating the semiconductor device according to Embodiment 1;

FIG. 15 is a cross-sectional view illustrating a portion of the processes of the method for fabricating the semiconductor device according to Embodiment 1;

FIG. 16 is a cross-sectional view illustrating a portion of the processes of the method for fabricating the semiconductor device according to Embodiment 1;

FIG. 17 is a diagram for describing an example of a staircase transition region in Comparative Example of Embodiment 1;

FIG. 18 is a cross-sectional view illustrating a portion of the processes of a method for fabricating a semiconductor device according to Modified Example of Embodiment 1;

FIG. 19 is a cross-sectional view illustrating a portion of the processes of the method for fabricating the semiconductor device according to Modified Example of Embodiment 1; and

FIG. 20 is a cross-sectional view illustrating an example of a relationship between a contact and a dielectric film on a sidewall side in Modified Example of Embodiment 1.

### DETAILED DESCRIPTION

A semiconductor device according to an embodiment includes a plurality of conductive layers, a plurality of contacts, a plurality of dielectric members, a channel body, and a memory film, The plurality of conductive layers is stacked to be separated from each other and formed in a plate shape extending in a direction intersecting a stacking direction so as to extend over first and second regions. Each of the plurality of contacts penetrates a different number of conductive layers among the plurality of conductive layers and is connected to a different conductive layer of the plurality of conductive layers at a different one of positions of the plurality of conductive layers stacked in the first region. Each of the plurality of dielectric members is arranged from substantially same height position to a different one of height positions and connected to a different one of the plurality of contacts. The channel body is formed of a semiconductor material penetrating the plurality of conductive layers in the second region. The memory film including a charge storage film is provided between the plurality of conductive layers and the channel body in the second region.

Hereinafter, in the embodiment, a semiconductor device capable of avoiding connection with a conductive layer of the lower layer side in contact connection will be described.

In addition, in the following embodiment, a three-dimensional NAND flash memory device will be described as an example of the semiconductor device. Hereinafter, description will be made with reference to the drawings.

### Embodiment 1

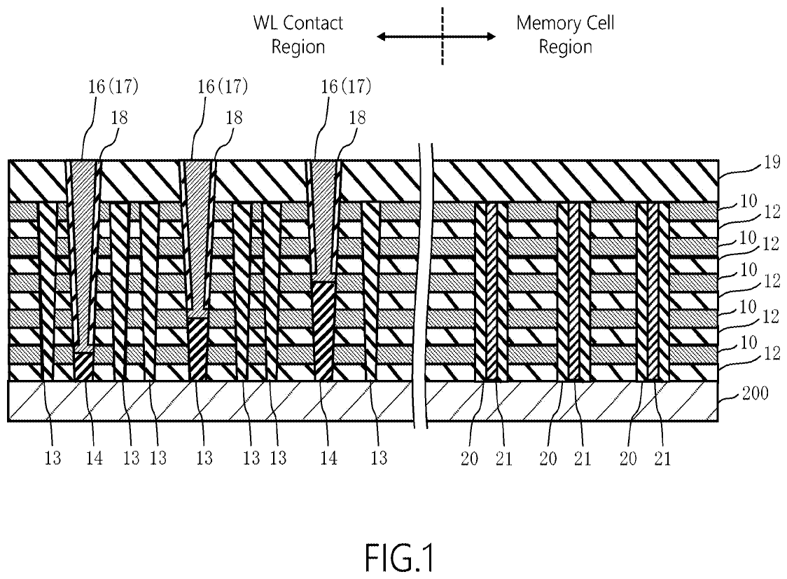

FIG. 1 is across-sectional view illustrating an example of a configuration of a semiconductor device according to Embodiment 1. In FIG. 1, in the semiconductor device according to Embodiment 1, conductive layers 10 of each layer of the plurality of conductive layers 10 that are stacked to be separated from each other and are to be word lines (WL) in the semiconductor storage device and dielectric layers 12 of each layer of the plurality of dielectric layers 12 that insulate the adjacent conductive layers 10 are alternately stacked on a semiconductor substrate 200 (substrate). The conductive layer 10 of each layer is a layer having a plate shape extending in a direction intersecting a stacking direction of the plurality of conductive layers 10 so as to extend over the word line contact region (first region) and the memory cell region (second region). In the example of FIG. 1, the dielectric layer 12 is first arranged on the semiconductor substrate 200, and the conductive layer 10 of the uppermost layer is covered with a dielectric film 19.

In FIG. 1, a plurality of contacts 16 each penetrates a different number of the conductive layers 10 from the side opposite to the semiconductor substrate 200 among the plurality of conductive layers 10 at a different one of the positions where the plurality of conductive layers 10 are stacked in the word line contact region. Then, each of the plurality of contacts 16 is connected to a different conductive layer 10 among the plurality of conductive layers 10. As described above, a stacked body of the plurality of conductive layers 10 and the plurality of dielectric layers 12 is not formed in the staircase shape constituting each terrace, and the stacked state of the same number of layers at the position where each contact 16 is connected is maintained. In the example of FIG. 1, for example, five conductive layers 10 are illustrated, and the state in which the contacts 16 are respectively connected to the three conductive layers 10 from the lower layer side among the five conductive layers 10 is illustrated. The contact 16 is connected to each of the other conductive layers 10, and the illustration is omitted. In addition, in the present specification, the direction in which the conductive layer 10 which the contact 16 connected to a certain conductive layer 10 penetrates is arranged is defined as the upward direction with respect to the certain conductive layer 10.

For example, the contact 16 connected to the conductive layer 10 of the first layer from the lower layer side penetrates the four conductive layers 10 of the upper layer side. The contact 16 connected to the conductive layer 10 of the second layer from the lower layer side penetrates the three conductive layers 10 of the upper layer side. The contact 16 connected to the conductive layer 10 of the third layer from the lower layer side penetrates the two conductive layers 10 of the upper layer side. A dielectric film 18 is arranged on the side surface of each contact 16 with a barrier metal film 17 interposed therebetween to insulate the conductive layer 10 which each contact 16 penetrates, from each contact 16. It goes without say that a conductive material is used as the material of each contact 16.

In addition, each of a plurality of contact base films 14 (dielectric members) is arranged from substantially the same height position to a different one of height positions, and is connected to a different contact 16 among the plurality of contacts 16. In the example of FIG. 1, each contact base film 14 is arranged from the height position of the inside of the dielectric layer 12 of the lower layer side of the conductive layer 10 of the lowermost layer or the lower surface of the dielectric layer 12 to the height position of the lower surface of each contact 16 to be connected. Therefore, the contact base films 14 penetrating different numbers of conductive layers 10 from the semiconductor substrate 200 side are arranged below the contacts 16 connected to the conductive layers 10 of the second layer from the lower layer side and subsequent layers. Below the contact 16 connected to the conductive layer 10 of the lowermost layer, the contact base film 14 extending to a height position of a middle portion of the conductive layer 10 of the lowermost layer is arranged. A dielectric material is used as the material of each contact base film 14. As illustrated in FIG. 1, each contact base film 14 of the plurality of contact base films 14 has, for example, a width size substantially the same as the width size of the corresponding contact 16 at the height position where the contact base film 14 is connected to the corresponding contact 16.

Further, in the example of FIG. 1, a plurality of pillars 13 having a function of maintaining a stacked structure of a plurality of dielectric layers 12 in a replacement process described later are arranged at positions not overlapping each contact 16 in the word line contact region.

In addition, in the memory cell region, a columnar channel body 21 penetrating the stacked body of the plurality of conductive layers 10 and the plurality of dielectric layers 12 in the stacking direction is arranged. A semiconductor material is used as the material of the channel body 21. Then, in the memory cell region, a memory film 20 including a charge storage film is arranged between each conductive layer 10 and the channel body 21. The memory film 20 is arranged in a cylindrical shape penetrating the stacked body of the plurality of conductive layers 10 and the plurality of dielectric layers 12 in the stacking direction so as to surround the entire side surface of the channel body 21. One memory cell is configured by a combination of the conductive layer 10 serving as a word line, the memory film 20, and the channel body 21 surrounded by the memory film 20. One NAND string is configured by a plurality of memory cells formed by connecting the memory cells in the conductive layer 10 of each layer that the same channel body 21 and the memory film 20 penetrate. In addition, a plurality of channel bodies 21 and memory films 20 surrounding the respective channel bodies 21 are arranged in one conductive layer 10. In the example of FIG. 1, a combination of three channel bodies 21 and memory films 20 is illustrated.

One-side ends of the channel bodies 21 are connected to respective bit line contacts and bit lines (not illustrated), which are different from each other, for example, in an upper layer from the stacked body. The other-side ends of the channel bodies 21 are connected to, for example, a common source line (not illustrated) in a lower layer from the stacked body. In addition, each columnar channel body 21 may have a cylindrical structure having a bottom formed by using a semiconductor material, and a core portion formed by using a dielectric material may be arranged inside the cylindrical structure.

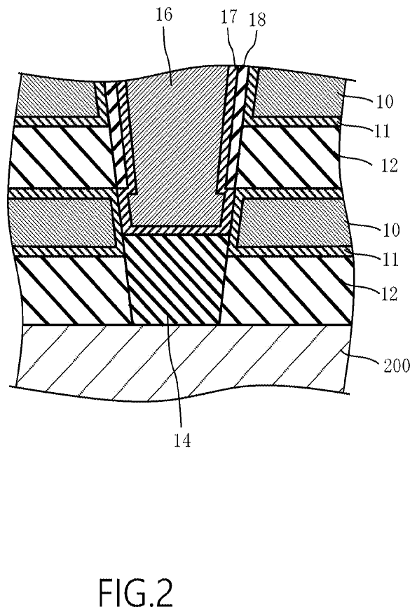

FIG. 2 is a cross-sectional view illustrating an example of a connection portion between the contact and the conductive layer in Embodiment 1. In the example of FIG. 2, for example, the connection portion between the conductive layer 10 of the lowermost layer and the contact 16 is illustrated. The connection method is the same for the conductive layer 10 and the contact 16 of the other layers. As illustrated in FIG. 2, each contact 16 of which lower surface is connected to the contact base film 14 is connected to the corresponding conductive layer 10 at each sidewall. The conductive layer 10 has an upper surface, a lower surface, and side surfaces covered with a barrier metal film 11. The entire side surfaces and the entire bottom surface of each contact 16 are covered with a barrier metal film 17. For this reason, as illustrated in FIG. 2, each contact 16 is connected to the corresponding conductive layer 10 at the sidewall with the barrier metal films 17 and 11 interposed therebetween. In addition, as illustrated in FIG. 2, each contact 16 is connected to the contact base film 14 with the barrier metal film 17 interposed therebetween. In addition, the side surface of each contact 16 of the upper layer side from the conductive layer 10 to be connected are covered with the dielectric film 18.

In Embodiment 1, each contact 16 is arranged after forming each contact base film 14 of which height is adjusted. Accordingly, it is possible to prevent each contact 16 from penetrating the conductive layer 10 of the lower layer side from the conductive layer 10 to be expected to be connected. In addition, in the plurality of conductive layers 10, one or more lower layers of the lower layer side including the conductive layer 10 of the lowermost layer and one or more upper layers of the upper layer side including the conductive layer 10 of the uppermost layer may constitute the conductive layer 10 serving as the selection gate line.

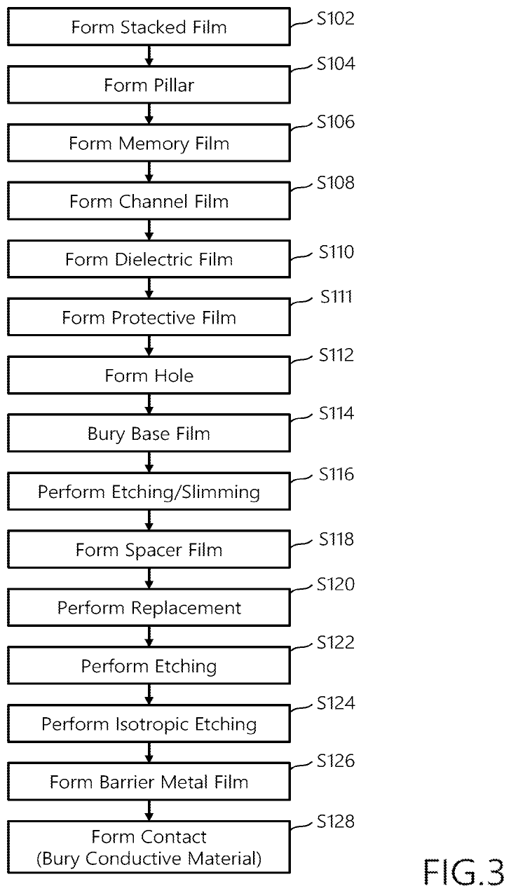

FIG. 3 is a flowchart illustrating main processes of the method for fabricating the semiconductor device according to Embodiment 1. In FIG. 3, in the method for fabricating the semiconductor device according to Embodiment 1, a series of processes such as a stacked film forming process (S102), a pillar forming process (S104), a memory film forming process (S106), a channel film forming process (S108), a dielectric film forming process (S110), a protective film forming process (S111), a hole forming process (S112), a base film burying process (S114), an etching/slimming process (S116), a spacer film forming process (S118), a replacement process (S120), an etching process (S122), an isotropic etching process (S124), a barrier metal film forming process (S126), and a contact forming process (S128) are performed.

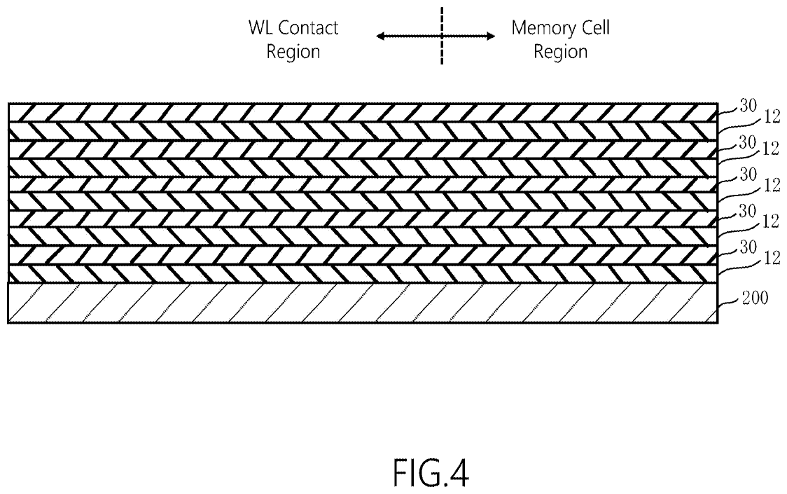

FIG. 4 is a cross-sectional view illustrating a portion of the processes of the method for fabricating the semiconductor device according to Embodiment 1. FIG. 4 illustrates the stacked film forming process (S102) of FIG. 3. The subsequent processes will be described later.

In FIG. 4, as the stacked film forming process (S102), first, a sacrificial film layer 30 (first layer) and a dielectric layer 12 are alternately stacked on the semiconductor substrate 200, by using, for example, an atomic layer deposition (ALD) or atomic layer chemical vapor deposition (ALCVD) method, or a chemical vapor deposition (CVD) method. In the example of FIG. 4, first, the dielectric layer 12 is formed on the semiconductor substrate 200, and after that, the sacrificial film layer 30 and the dielectric layer 12 are alternately stacked. By such a process, a stacked film (stacked body) in which the sacrificial film layers 30 of the respective layers of the plurality of sacrificial film layers 30 and the dielectric layers 12 of the respective layers of the plurality of dielectric layers 12 are alternately stacked is formed. It is preferable that, for example, a silicon nitride film (SiN film) is used as the sacrificial film used for the sacrificial film layer 30. In addition, it is preferable that for example, a silicon oxide film (SiO₂ film) is used as the dielectric film used for the dielectric layer 12. In addition, for example, a silicon wafer having a diameter of 300 mm is used as the semiconductor substrate 200. In addition, on the semiconductor substrate or in the semiconductor substrate in which the sacrificial film layers 30 and the dielectric layers 12 are alternately stacked, other dielectric films, wires, contacts, and/or semiconductor elements such as transistors, which are not illustrated, may be formed.

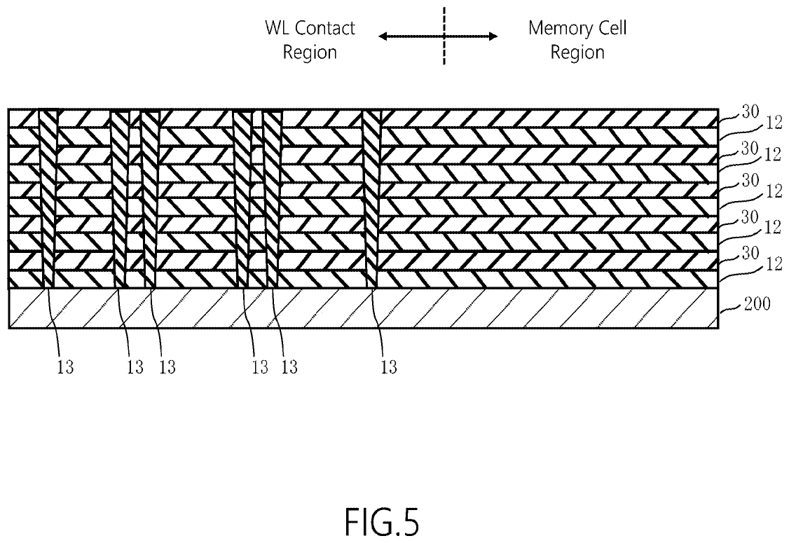

FIG. 5 is a cross-sectional view illustrating a portion of the processes of the method for fabricating the semiconductor device according to Embodiment 1. FIG. 5 illustrates the pillar forming process (S104) of FIG. 3. The subsequent processes will be described later.

In FIG. 5, as the pillar forming process (S104), an opening (hole) having, for example, a circular cross section is formed from above, for example, the sacrificial film layer 30 of the uppermost layer of the stacked film to penetrate the above-described stacked film. Herein, a plurality of holes for forming the pillars are formed in a region that will serve as a word line contact region later. In addition, although not illustrated, it is preferable that a plurality of memory holes are simultaneously formed in the memory cell region. The plurality of holes for forming the pillars and the plurality of memory holes are not limited to be formed together, and may be formed separately.

Specifically, in the state where a resist film is formed on the sacrificial film layer 30 through a lithography process such as a resist coating process and an exposing process (not illustrated), by removing the exposed sacrificial film layer 30 and the stacked film of the sacrificial film layer 30 and the dielectric layer 12 located in the lower layer by the anisotropic etching method, the pillar forming holes and the memory holes can be formed to be substantially perpendicular to the surface of the sacrificial film layer 30. For example, as an example, the pillar forming holes and the memory holes may be formed by a reactive ion etching (RIE) method. In addition, in Embodiment 1, the stacked body is formed so that the sacrificial film layer 30 out of the sacrificial film layer 30 and the dielectric layer 12 becomes the exposed surface, and embodiments are not limited to this. It is also preferable that the stacked body is formed so that the dielectric layer 12 becomes the exposed surface.

Subsequently, the dielectric film for the pillar 13 is formed in the pillar forming hole, by using, for example, the ALD method, the ALCVD method, or the CVD method. Herein, it is preferable that deposition is performed until the dielectric film for the pillar 13 is completely buried in the pillar forming hole. It is preferable that, for example, an SiO₂ film is used as the dielectric film for the pillar 13.

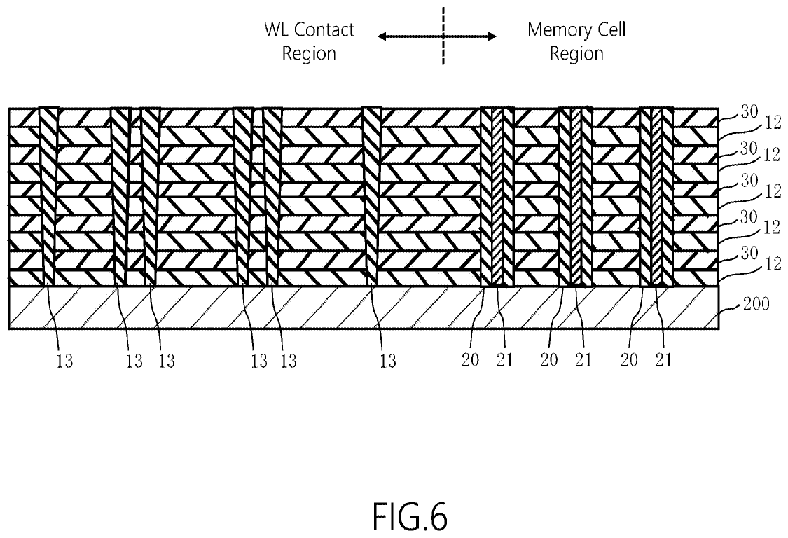

FIG. 6 is a cross-sectional view illustrating a portion of the processes of the method for fabricating the semiconductor device according to Embodiment 1. FIG. 6 illustrates the memory film forming process (S106) and the channel film forming process (S108) of FIG. 3. The subsequent processes will be described later.

In FIG. 6, as the memory film forming process (S106), the memory film 20 is formed in each of the formed memory holes. Alternatively, in a case where the memory holes are formed separately from the pillar forming process (S104), the memory holes are first formed by the above-described method, and the memory films 20 are formed in the respective memory holes formed.

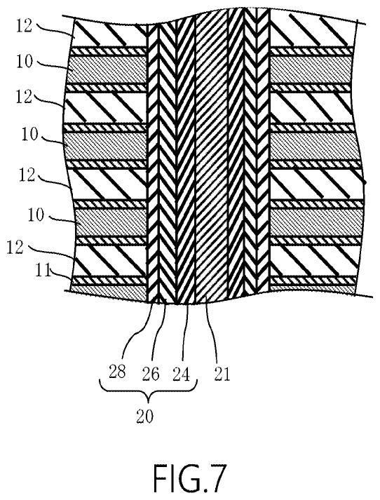

FIG. 7 is a cross-sectional view illustrating an example of a configuration of the memory cell region in Embodiment 1. FIG. 7 illustrates a state after the sacrificial film layer 30 is replaced with the conductive layer 10 (the barrier metal film 11 and the metal film). The memory film 20 has a block dielectric film 28, a charge storage film 26, and a tunnel dielectric film 24. Hereinafter, the internal process will be specifically described.

As the block film forming process, the block dielectric film 28 is formed along the sidewall surface of each memory hole by using, for example, the ALD method, the ALCVD method, or the CVD method. The block dielectric film 28 is a film that suppresses the flow of charges between the charge storage film 26 and the conductive layer 10. It is preferable that, for example, an aluminum oxide (Al₂O₃) film or an SiO₂ film is used as the material of the block dielectric film 28. As a result, the block dielectric film 28 arranged in a cylindrical shape along the sidewall surface of the memory hole can be formed as a portion of the memory film 20.

Subsequently, as the charge storage film forming process, the charge storage film 26 is formed along the sidewall surface of the block dielectric film 28 in each memory hole by using, for example, the ALD method, the ALCVD method, or the CVD method. The charge storage film 26 is a film containing a material capable of storing charges. It is preferable that, for example, SiN is used as the material of the charge storage film 26. As a result, the charge storage film 26 arranged in a cylindrical shape along the inner sidewall surface of the block dielectric film 28 can be formed as a portion of the memory film 20.

Subsequently, as the tunnel dielectric film forming process, the tunnel dielectric film 24 is formed along the sidewall surface of the charge storage film 26 in each memory hole by using, for example, the ALD method, the ALCVD method, or the CVD method. The tunnel dielectric film 24 is a dielectric film that has an insulating property and allows a current to flow when a predetermined voltage is applied. It is preferable that, for example, SiO₂ is used as the material of the tunnel dielectric film 24. As a result, the tunnel dielectric film 24 arranged in a cylindrical shape along the inner sidewall surface of the charge storage film 26 can be formed as a portion of the memory film 20.

In the above-described example, a case where the block dielectric film 28 is formed before the formation of the charge storage film 26 is illustrated, and embodiments are not limited to this. In the memory film forming process (S106), the charge storage film 26 and the tunnel dielectric film 24 are formed, and before the barrier metal film and the conductive material are buried in the replacement process (S120) described later, the block dielectric film 28 may be formed through a replacement groove described later.

Subsequently, as the channel film forming process (S108), a channel film serving as a channel body 21 is formed in a columnar shape along the inner sidewall surface of the tunnel dielectric film 24 in each memory hole by using, for example, the ALD method, the ALCVD method, or the CVD method. A semiconductor material is used as the material of the channel film. For example, it is preferable to use silicon (Si) doped with impurities. As a result, the channel body 21 can be formed in a columnar shape along the entire circumference of the inner sidewall surface of the tunnel dielectric film 24.

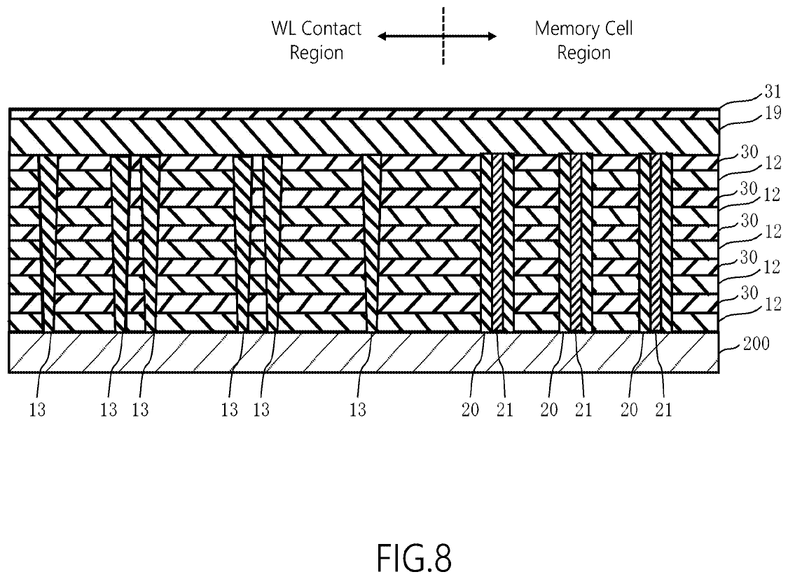

FIG. 8 is a cross-sectional view illustrating a portion of the processes of the method for fabricating the semiconductor device according to Embodiment 1. FIG. 8 illustrates the dielectric film forming process (S110) and the protective film forming process (S111) of FIG. 3. The subsequent processes will be described later.

In FIG. 8, as the dielectric film forming process (S110), the dielectric film 19 is formed on the stacked body on which the pillars 13, the memory film 20, and the channel body 21 are formed by using, for example, the ALD method, the ALCVD method, or the CVD method. It is preferable that, for example, SiO₂ is used as the material of the dielectric film 19.

Subsequently, as the protective film forming process (S111), a protective film 31 for protecting the dielectric film 19 during etching is formed on the dielectric film 19 by using, for example, the ALD method, the ALCVD method, or the CVD method. It is preferable that, for example, a silicon nitride oxide (SiNO) film having an etching rate smaller than that of the dielectric film 19 is used as the material of the protective film 31.

In addition, herein, the dielectric film forming process (S110) and the protective film forming process (S111) are performed after the pillars 13, the memory film 20, and the channel body 21 are formed, and embodiments are not limited to this. The pillars 13, the memory film 20, and the channel body 21 may be formed after the dielectric film forming process (S110) and the protective film forming process (S111) are performed. Alternatively, the memory film 20 and the channel body 21 may be formed after the dielectric film forming process (S110) and the protective film forming process (S111) are performed.

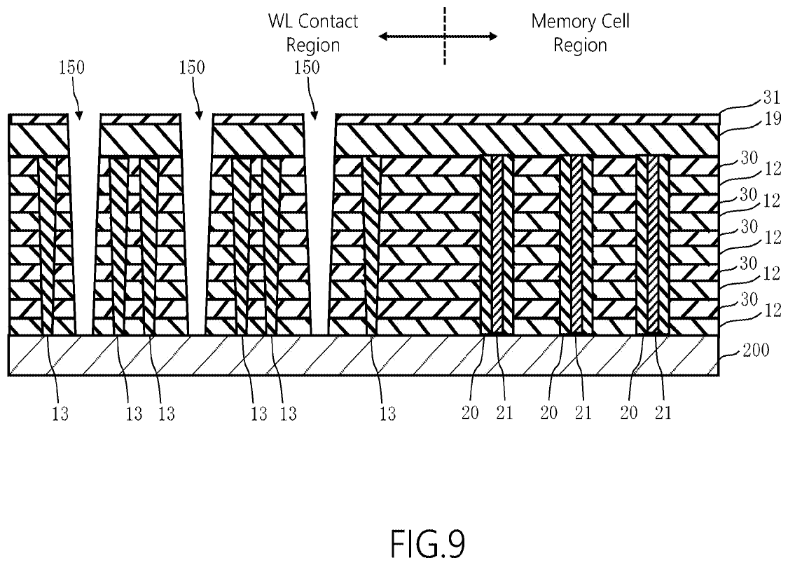

FIG. 9 is a cross-sectional view illustrating a portion of the processes of the method for fabricating the semiconductor device according to Embodiment 1. FIG. 9 illustrates the hole forming process (S112) of FIG. 3. The subsequent processes will be described later.

In FIG. 9, as the hole forming process (S112), an opening (hole 150) having, for example, a circular cross section is formed from above the protective film 31 to penetrate the dielectric film 19 and the above-described stacked film. Herein, the plurality of holes 150 for forming contacts are formed in a region which will serves as a word line contact region later. In the state where a resist film is formed on the protective film 31 through a lithography process such as a resist coating process and an exposing process (not illustrated), by removing the exposed protective film 31, the dielectric film 19 located in the lower layer, and the stacked film of the sacrificial film layer 30 and the dielectric layer 12 by the anisotropic etching method, the plurality of holes 150 can be formed to be substantially perpendicular to the surface of the protective film 31. Herein, the plurality of holes 150 having the same depth are formed in the stacked film. The example of FIG. 9 illustrates a case where the plurality of holes 150 having the same depth and penetrating the entire stacked film are formed. The plurality of holes 150 are formed at least up to the height position of the lower layer side of the sacrificial film layer 30 of the lowermost layer. As an example, the plurality of holes 150 maybe formed by, for example, a reactive ion etching (RIE) method.

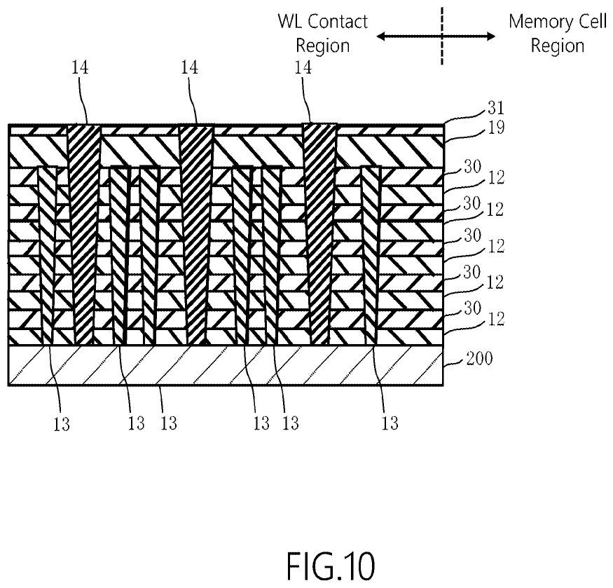

FIG. 10 is a cross-sectional view illustrating a portion of the processes of the method for fabricating the semiconductor device according to Embodiment 1. FIG. 10 illustrates the base film burying process (S114) of FIG. 3. The subsequent processes will be described later. In addition, in FIG. 10 and subsequent process cross-sectional views, the illustration of the memory cell region will be omitted.

In FIG. 10, as the base film burying process (S114), the contact base film 14 (dielectric member) is buried in the plurality of holes 150 by using, for example, the ALD method, the ALCVD method, or the CVD method. Herein, it is preferable that deposition is performed until the dielectric film for the contact base film 14 is completely buried in all the holes 150. It is preferable that, for example, an SiO₂ film is used as a dielectric film for the contact base film 14. In addition, the dielectric film for the contact base film 14 deposited outside the hole 150 may be removed by a chemical mechanical polishing (CMP) method or the like.

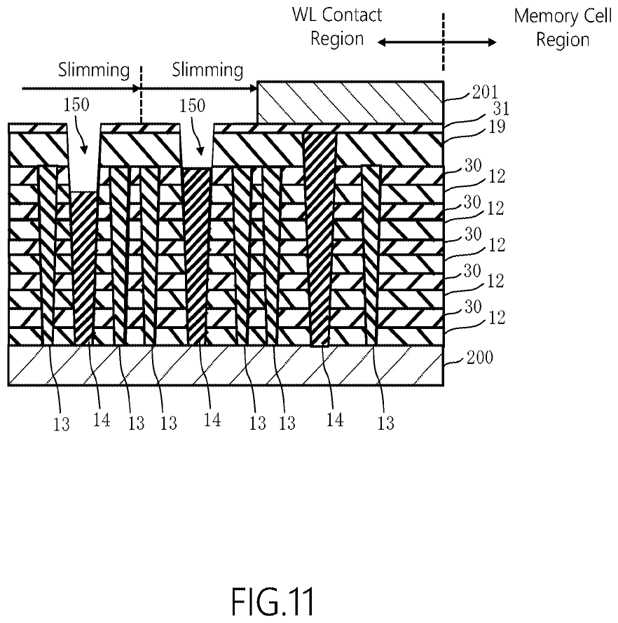

FIG. 11 is a cross-sectional view illustrating a portion of the processes of the method for fabricating the semiconductor device according to Embodiment 1. FIG. 11 illustrates a stage in a middle of the etching/slimming process (S116) of FIG. 3. The subsequent processes will be described later.

In FIG. 11, as the etching/slimming process (S116), a portion of the contact base film 14 is removed from each of the holes 150 so that the heights of the contact base films 14 are different for the respective holes 150 while maintaining the stacked state of the stacked film at the positions where the plurality of holes 150 are formed. Herein, the plurality of contact base films 14 are processed to have a staircase shape.

Specifically, the resist film is formed on the dielectric film 19 covered with the protective film 31. Patterning is performed on the resist film to expose the position of the contact hole 150 connected to the conductive layer of the lowermost layer in the word line contact region. Then, for example, an anisotropic etching process such as RIE using the resist film as a mask and a slimming process such as ashing for reducing the volume of the resist film are alternately repeated.

By a first anisotropic etching process, an upper layer portion of the contact base film 14 in the contact hole 150 connected to the conductive layer of the lowermost layer is selectively removed. Due to the protective film 31, the dielectric film 19 can be allowed to remain without being etched. Then, the side surface of the resist film is allowed to recede by a slimming process, and the position of the contact hole 150 connected to the conductive layer of the second layer from the lowermost layer is exposed. By alternately repeating the anisotropic etching process and the slimming process, as illustrated in FIG. 11, each contact base film 14 is allowed to remain so as to have a staircase shape in which the height positions are sequentially different in the respective holes 150.

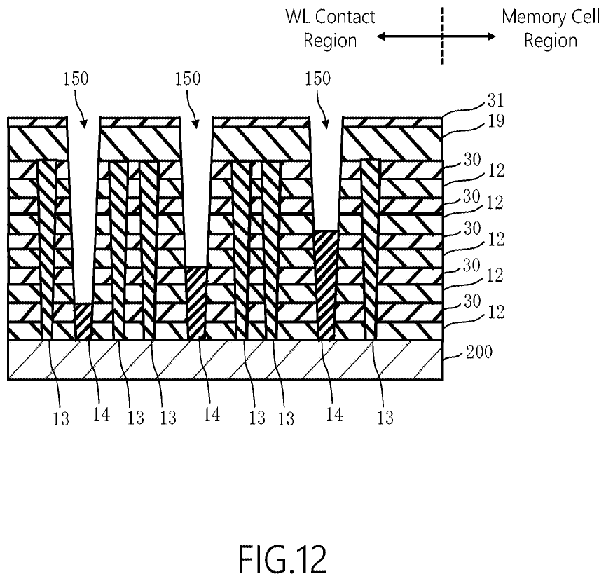

FIG. 12 is a cross-sectional view illustrating a portion of the processes of the method for fabricating the semiconductor device according to Embodiment 1. FIG. 12 illustrates the end stage of the etching/slimming process (S116) of FIG. 3. The subsequent processes will be described later.

By alternately repeating the anisotropic etching process and the slimming process, as illustrated in FIG. 12, the height position of the upper surface of each contact base film 14 is adjusted to, for example, a height position substantially the same as that of the upper surface of the sacrificial film layer 30 corresponding to each layer in order by one layer or a height position slightly lower than that of the upper surface of the sacrificial film layer 30 corresponding to each layer (in a range not exceeding the thickness of the sacrificial film layer 30) from the sacrificial film layer 30 of the lowermost layer toward the sacrificial film layer 30 of the upper layer.

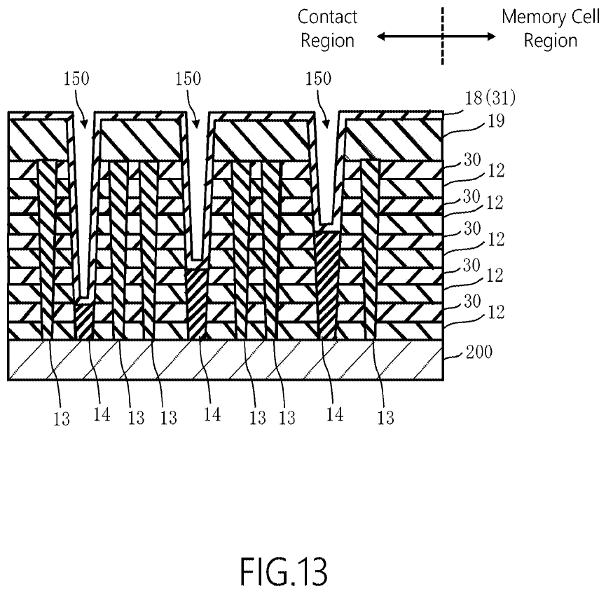

FIG. 13 is a cross-sectional view illustrating a portion of the processes of the method for fabricating the semiconductor device according to Embodiment 1. FIG. 13 illustrates the spacer film forming process (S118) of FIG. 3. The subsequent processes will be described later.

In FIG. 13, as the spacer film forming process (S118), by using, for example, the ALD method, the ALCVD method, or the CVD method, the dielectric films 18 serving as the spacer films are formed on the bottom surfaces and the sidewalls of the plurality of holes 150 having different heights of the contact base films 14. Herein, the dielectric films 18 are formed on the bottom surfaces and sidewalls of the plurality of holes 150 of which height has been adjusted by the contact base film 14. It is preferable that, for example, SiNO, which has a smaller etching rate than the contact base film 14, is used as the material of the dielectric film 18. The dielectric film 18 may be deposited on the protective film 31 of the same kind.

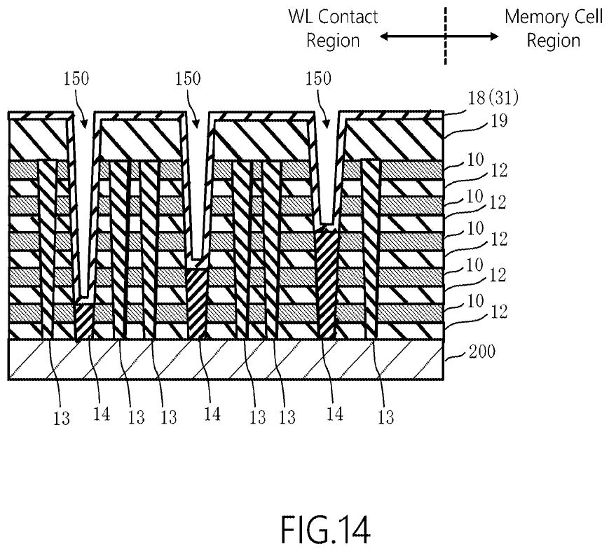

FIG. 14 is a cross-sectional view illustrating a portion of the processes of the method for fabricating the semiconductor device according to Embodiment 1. FIG. 14 illustrates the replacement process (S120) of FIG. 3. The subsequent processes will be described later.

In FIG. 14, as the replacement process (S120), the stacked sacrificial film layer 30 is replaced with the conductive layer 10. Herein, the sacrificial film layer 30 is replaced with the conductive layer 10 in a state where the dielectric film 18 on the bottom surfaces of the plurality of holes 150 is formed. Specifically, the process is performed as follows. First, the sacrificial film layer 30 of each layer is removed by etching with a replacement groove (not illustrated) interposed therebetween by a wet etching method (for example, hot phosphoric acid process). As a result, a space is formed between the dielectric layers 12 of each layer. In the word line contact region, the pillars 13 that intersect the dielectric layers 12 of the respective layers and extend in the stacking direction serve as support members (pillars), and thus, the dielectric layers 12 of the respective layers can be supported so as not to collapse. In the memory cell region, the memory film 20 and the channel body 21 that intersect the dielectric layers 12 of the respective layers and extend in the stacking direction serve as support members (pillars), and the dielectric layers 12 of the respective layers can be supported so as not to collapse.

Then, the barrier metal film 11 illustrated in FIG. 2 is first formed on the upper and lower wall surfaces and sidewalls of the space between the dielectric layers 12 of each layer through the replacement groove interposed therebetween by using the ALD method, the ALCVD method, or the CVD method. After that, by using the ALD method, the ALCVD method, or the CVD method, the conductive material serving as the word line is buried in the space between the dielectric layers 12 of each layer to form the conductive layer 10. It is preferable that, for example, a titanium nitride (TiN) is used as the barrier metal film 11. In addition, it is preferable that tungsten (W) is used as the conductive material of the conductive layer 10.

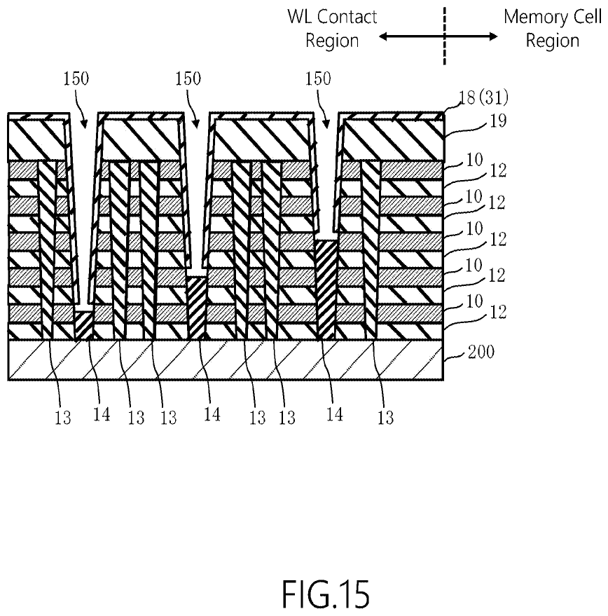

FIG. 15 is a cross-sectional view illustrating a portion of the processes of the method for fabricating the semiconductor device according to Embodiment 1. FIG. 15 illustrates the etching process (S122) and the isotropic etching process (S124) of FIG. 3. The subsequent processes will be described later.

In FIG. 15, as the etching process (S122), bottom portions of the dielectric films 18 formed on the bottom surfaces of the plurality of holes 150 is removed by etching. As an example, the bottom portions of the dielectric films 18 may be removed, for example, by a reactive ion etching (RIE) method having directivity.

Then, as the isotropic etching process (S124), top portions of the contact base films 14 exposed by etching are removed by isotropic etching. Herein, it is preferable that a wet etching method is used. The etching amount is adjusted to a size smaller than the thickness of the conductive layer 10, and the etching is finished before reaching the dielectric layer 12 of the lower layer side. As a result, as illustrated in FIG. 2, the barrier metal film 11 covering the conductive layer 10 can be exposed on the side surface side of the bottom of each hole 150.

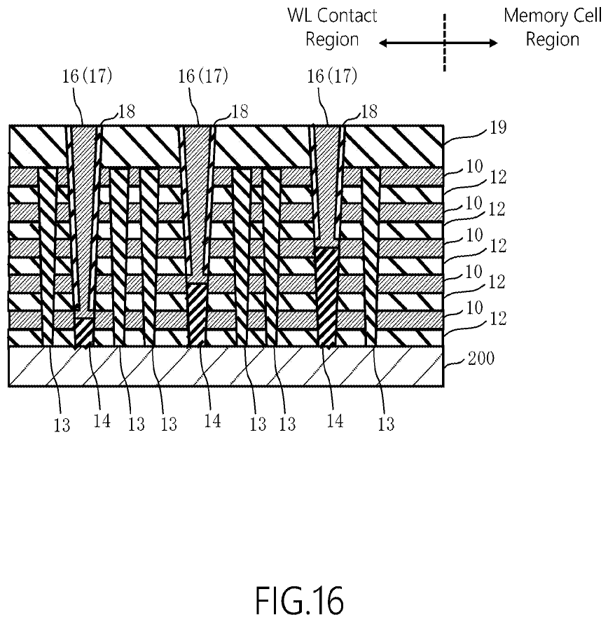

FIG. 16 is a cross-sectional view illustrating a portion of the processes of the method for fabricating the semiconductor device according to Embodiment 1. FIG. 16 illustrates the barrier metal film forming process (S126) and the contact forming process (S128) of FIG. 3.

In FIG. 16, as the barrier metal film forming process (S126), the barrier metal film 17 illustrated in FIG. 2 is formed on the wall surfaces and the bottom surfaces of the spaces in the plurality of holes 150 by using the ALD method, the ALCVD method, or the CVD method.

Then, as the contact forming process (S128), a conductive material is buried in the plurality of holes 150 in which the contact base films 14 having different heights remain. For example, W is buried. As a result, as illustrated in FIG. 16, each contact 16 is connected to the corresponding conductive layer 10 at the side surface. In addition, the conductive layer 10 which each contact 16 penetrates is insulated from each contact 16 by the dielectric film 18 serving as a sidewall film arranged on the sidewall of each contact 16.

As described above, according to Embodiment 1, by raising each of the insides of the plurality of holes 150 formed by the batch processing and having the same depth up to the desired height position by the contact base film 14, it is possible to prevent the penetration to the lower layer side in the case of forming the contacts 16. By adjusting the raising up by the contact base film 14, it is possible to prevent the penetration to the lower layer side in the case of forming the contact 16 in any one of from the shallow hole 150 to the deep hole 150. In addition, the processing of the staircase structure for the stacked film including the conductive layer (sacrificial film layer) and the dielectric layer in the related art can be allowed to be unnecessary.

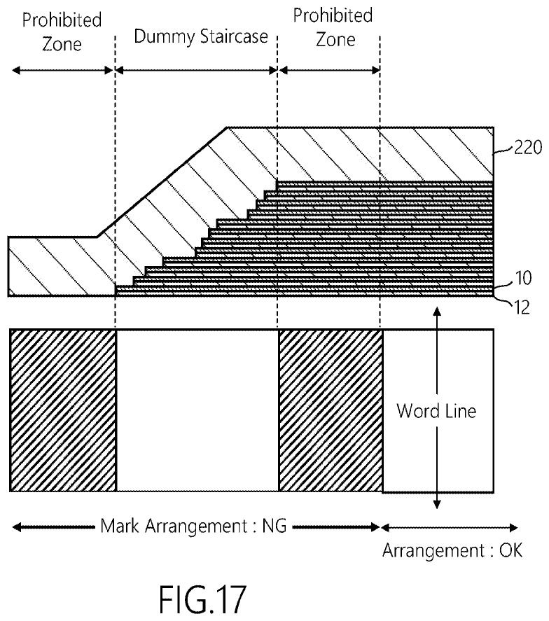

FIG. 17 is a diagram for describing an example of a staircase transition region in Comparative Example of Embodiment 1. In a staircase structure for the stacked film including the conductive layer 10 (sacrificial film layer) and the dielectric layer 12 in the related art as Comparative Example, a staircase structure (dummy staircase) is formed in a direction perpendicular to the direction in which the conductive layer 10 serving as the word line extends. Since the staircase structure portion is inclined, even when the resist film 220 is applied, the resist film is formed obliquely. For this reason, the patterning accuracy deteriorates, and thus, it is difficult to arrange alignment marks. In addition, it is necessary to provide mark arrangement prohibited zones as margins on both sides of the staircase structure. Since such a transition region tends to expand as the number of stacked layers of the sacrificial film layer and the dielectric layer increases, the reduction of the chip size is hindered. On the other hand, in Embodiment 1, since the staircase structure is not formed in the stacked film including the sacrificial film layer and the dielectric layer, the staircase transition region can be omitted. Therefore, it is possible to reduce the chip size accordingly. In addition, since the staircase structure is not formed in the stacked film, it is possible to relax the restriction on the mark arrangement position.

In addition, in the related art, it has been necessary to bury the dielectric film in the terrace portion and then perform the planarization process after forming the staircase structure of the stacked film. In Embodiment 1, since such a staircase structure of the stacked film is not formed, the number of processes can be reduced accordingly.

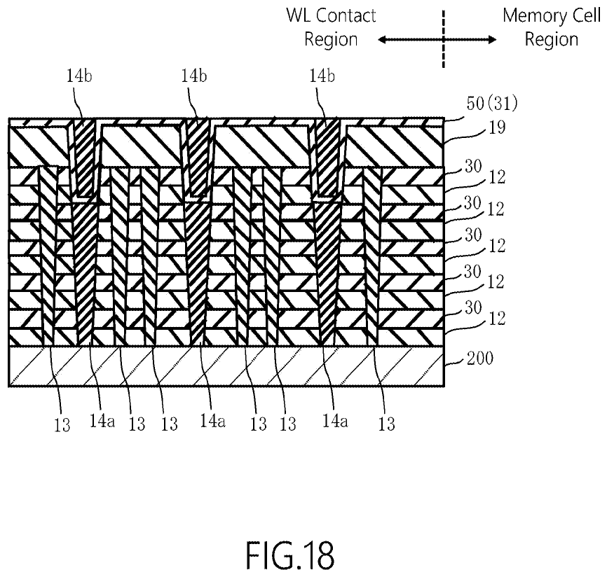

FIG. 18 is a cross-sectional view illustrating a portion of the processes of the method for fabricating a semiconductor device according to Modified Example of Embodiment 1. FIG. 18 illustrates the base film burying process (S114) of FIG. 3.

In FIG. 18, as the base film burying process (S114) in Modified Example of Embodiment 1, a contact base film 14a (base film) is buried up to height positions of a middle portions of the plurality of holes 150 by using, for example, the ALD method, the ALCVD method, or the CVD method. Then, a spacer film 50 is formed on the bottom surfaces and the sidewalls of the plurality of holes 150 in which the contact base film 14a is buried, by using, for example, the ALD method, the ALCVD method, or the CVD method. It is preferable that the thickness of the spacer film 50 is set to be, for example, smaller than that of the sacrificial film layer 30. Then, a contact base film 14b (base film) is buried in the plurality of holes 150 by using, for example, the ALD method, the ALCVD method, or the CVD method. Finally, the contact base film 14b is completely buried in all of the plurality of holes 150 with the spacer film 50 interposed therebetween in a middle portion. It is preferable that, for example, SiNO is used as the material for the spacer film 50.

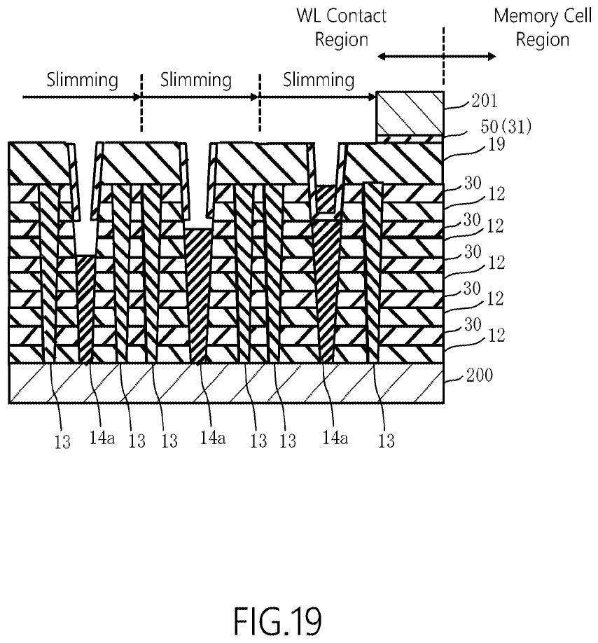

FIG. 19 is a cross-sectional view illustrating a portion of processes of a method for fabricating a semiconductor device according to Modified Example of Embodiment 1. FIG. 19 illustrates the etching/slimming process (S116) of FIG. 3.

In FIG. 19, as the etching/slimming process (S116) in Modified Example of Embodiment 1, patterning is performed to expose the position of the contact hole 150 connected to the conductive layer of the lowermost layer in the word line contact region. Then, for example, an anisotropic etching process such as RIE using the resist film as a mask and a slimming process such as asking for reducing the volume of the resist film are alternately repeated. Since the spacer film 50 has a smaller etching rate than the contact base film 14, the spacer film 50 functions as an etching stopper. Therefore, in the anisotropic etching process, the etching is temporarily stopped at the height position of the spacer film 50. Then, after removing the spacer film 50 on the bottom surface of the hole 150 by etching and performing the slimming process of the resist film, the anisotropic etching process of the contact base film 14 is performed together with the region of the next layer. As a result, it is possible to absorb variations in processing at the time of etching the contact base film 14.

In the example of FIG. 19, an example where the spacer film 50 is arranged on the slightly upper layer side from the half of the stacked film is illustrated. However, since the variation in processing accuracy increases as the position is on the lower layer side, it is more preferable that the height position where the spacer film 50 is arranged is set to the lower layer side from the half of the stacked film. Then, by alternately repeating the anisotropic etching process and the slimming process, as illustrated in FIG. 12, the height position of the upper surface of each contact base film 14 is adjusted to a desired height position.

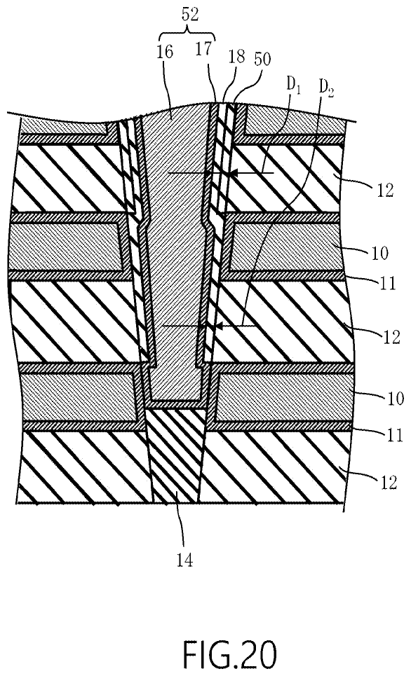

FIG. 20 is a cross-sectional view illustrating an example of a relationship between a contact and a dielectric film on a sidewall side in Modified Example of Embodiment 1. In Modified Example of Embodiment 1, the spacer film 50 is arranged on the sidewall up to a depth of a middle portion of each hole 150. Then, in a state where the spacer film 50 is allowed to remain on the sidewall, after that, the dielectric film 18 of the same kind is further arranged. For this reason, as illustrated in FIG. 20, in a portion of the plurality of contacts 16, the thickness of each dielectric film 52 arranged on the sidewall of the corresponding contact 16 is changed at a height position of a middle portion extending to the conductive layer 10 to which the corresponding contact 16 is connected. In the example of FIG. 20, the change in the thickness of the dielectric film 52 occurs at substantially the same height position.

Specifically, in a portion of the contacts 16 connected to the conductive layer 10 of the lower layer side from the position where the bottom surface of the spacer film 50 is arranged, the dielectric film 52 configured with the dielectric film 18 and the spacer film 50 is arranged on the sidewall of the contact 16 above the height position of a middle portion extending to the conductive layer 10 to be connected. On the other hand, the dielectric film 18 is arranged on the sidewall of the contact 16 from the height position of the middle portion to the conductive layer 10 to be connected. Therefore, a thickness D1 of the dielectric film 52 configured with both the dielectric film 18 and the spacer film 50 is larger than a thickness D2 of the dielectric film configured with only the dielectric film 18 without the spacer film 50.

As described above, according to Embodiment 1, it is possible to avoid connection to the conductive layer of the lower layer side in the contact connection.

Heretofore, the embodiment has been described above reference to the specific examples. However, embodiments are not limited to these specific examples.

In addition, with respect to the thickness of each film, the size, shape, and number of the openings, and the like, those desired for the semiconductor integrated circuits and various semiconductor elements can be appropriately selected and used.

Besides, all semiconductor devices which include the elements according to embodiments and of which design can be appropriately changed by those skilled in the art are included in the scope of embodiments.

In addition, for the simplification of description, methods that are usually used in the semiconductor industry, for example, a photolithography process, cleaning before and after processing, and the like are omitted, and it goes without saying that these methods may be included.

While certain embodiments have been described, these embodiments have been presented by way of example only, and are not intended to limit the scope of the inventions. Indeed, the novel methods and devices described herein may be embodied in a variety of other forms; furthermore, various omissions, substitutions and changes in the form of the methods and devices described herein may be made without departing from the spirit of the inventions. The accompanying claims and their equivalents are intended to cover such forms or modifications as would fall within the scope and spirit of the inventions.

What is claimed is:

1. A semiconductor device comprising:
a plurality of conductive layers stacked to be separated from each other and formed in a plate shape extending in a direction intersecting a stacking direction so as to extend over first and second regions;
a plurality of contacts each penetrating a different number of conductive layers among the plurality of conductive layers and connected to a different conductive layer of the plurality of conductive layers at a different one of positions of the plurality of conductive layers stacked in the first region;
a plurality of dielectric members each arranged from substantially same height position to a different one of height positions and connected to a different one of the plurality of contacts;
a channel body formed of a semiconductor material penetrating the plurality of conductive layers in the second region; and
a memory film including a charge storage film provided between the plurality of conductive layers and the channel body in the second region.

2. The device according to claim 1, wherein each of the plurality of contacts is connected to a corresponding conductive layer at a sidewall.

3. The device according to claim 1, further comprising a plurality of dielectric films each arranged on a sidewall of a corresponding contact of the plurality of contacts, each dielectric film insulating the conductive layers, which the corresponding contact penetrates, from the corresponding contact,
wherein a thickness of the dielectric film arranged on the sidewall of a portion of the plurality of contacts is changed at a position of a middle portion extending to a corresponding conductive layer to which the portion of the plurality of contacts is connected.

4. The device according to claim 1, wherein the plurality of conductive layers maintains a stacked state of a same number of layers at a position where each contact is connected.

5. The device according to claim 1, wherein, among the plurality of dielectric members, dielectric members connected to contacts connected to conductive layers of the second layer and subsequent layers from a lower layer side among the plurality of conductive layers each penetrate a different number of conductive layers among the plurality of conductive layers.

6. The device according to claim 5, wherein, among the plurality of dielectric members, a dielectric member connected to a corresponding contact connected to a conductive layer of the lowermost layer among the plurality of conductive layers is connected to the corresponding contact at a height position of a middle portion of the conductive layer of the lowermost layer.

7. The device according to claim 1, further comprising a plurality of dielectric layers insulating between adjacent conductive layers among the plurality of conductive layers,
wherein, among the plurality of dielectric members, dielectric members connected to contacts connected to conductive layers of the second layer and subsequent layers from a lower layer side among the plurality of conductive layers each penetrate a different number of dielectric layers among the plurality of dielectric layers.

8. The device according to claim 1,
wherein the substantially same height position is located on a lower layer side of a conductive layer of the lowermost layer among the plurality of conductive layers, and
each of plurality of dielectric members is arranged from the substantially same height position on the lower layer side of the conductive layer of the lowermost layer among the plurality of conductive layers to the different one of the height positions.

9. The device according to claim 1, wherein each of the plurality of dielectric members has a width size substantially same as a width size of a corresponding contact at a height position where each dielectric member is connected to the corresponding contact.

10. The device according to claim 3, wherein a change in the thickness of the dielectric film occurs at substantially same height position among the plurality of dielectric films arranged on sidewalls of portions of the plurality of contacts.

11. The device according to claim 1, wherein the plurality of contacts have side surfaces and bottom surfaces covered with a barrier metal film.

12. A method for fabricating a semiconductor device, comprising:
forming a stacked film by alternately stacking a first layer and a dielectric layer above a substrate;
forming a plurality of openings having substantially same depth in the stacked film;
burying base films in the plurality of openings;
removing portions of the base films from insides of the plurality of openings so as to allow heights of the base films for respective openings to be different while maintaining a stacked state of the stacked film at positions where the plurality of openings being formed; and
burying a conductive material in the insides of the plurality of openings, the base films having different heights remaining in the openings.

13. The method according to claim 12, further comprising replacing the first layer stacked with a conductive layer.

14. The method according to claim 13, further comprising forming dielectric films on sidewalls and bottom surfaces of the plurality of openings, the base films having different heights remaining in the openings, before the replacing.

15. The method according to claim 14, further comprising removing bottom portions of the dielectric films formed on the bottom surfaces of the plurality of openings, after the replacing.

16. The method according to claim 15, further comprising isotropically etching top portions of the base films exposed by removing the bottom portions of the dielectric films formed on the bottom surfaces of the plurality of openings.

17. The method according to claim 16, wherein an etching amount of the isotropically etching is adjusted to a size smaller than a thickness of the conductive layer.

18. The method according to claim 16, wherein the conductive material is buried after the isotropically etching.

19. The method according to claim 14, wherein the dielectric films formed on the sidewalls of the plurality of openings insulate between the conductive material and the conductive layer which the conductive material penetrates.

20. The method according to claim 14, wherein a material different from that of the base films is used as a material of the dielectric films.
